(19) United States
(12) Patent Application Publication
(10) Pub. No.: US 2025/0169326 A1
(43) Pub. Date: May 22, 2025

(54) BEZEL-LESS CAMERA AND SENSOR HOLE WITH FUNCTIONAL SUB-PIXEL

(71) Applicant: Applied Materials, Inc., Santa Clara, CA (US)

(72) Inventors: Chung-chia CHEN, Hsinchu City (TW); Jungmin LEE, Santa Clara, CA (US); Yu-Hsin LIN, Zhubei City (TW); Ji Young CHOUNG, Hwaseong-si (KR); Wen-Hao WU, San Jose, CA (US)

(21) Appl. No.: 18/949,389

(22) Filed: Nov. 15, 2024

Related U.S. Application Data
(60) Provisional application No. 63/600,377, filed on Nov. 17, 2023.

(51) Int. Cl. H10K 59/60; H10K 59/12; H10K 59/70; H10K 65/00; H10K 102/10

(52) U.S. Cl. CPC H10K 59/60; H10K 59/1201; H10K 59/70; H10K 65/00; H10K 2102/103

(57) ABSTRACT

Embodiments described herein relate to sub-pixel circuits, displays including sub-pixel circuits, and a method of forming sub-pixel circuits that may be utilized in a display such as an organic light-emitting diode (OLED) display. Some configurations of the displays described herein include a backplane and a plurality of sub-pixel circuits separated by adjacent overhang structures disposed over the backplane. The at least one sub-pixel circuit has sub-pixels surrounded by adjacent overhang structures. The sub-pixel circuit includes one or more organic light-emitting diode (OLED) sub-pixels and an organic photodiode (OPD) sub-pixel. The OLED sub-pixels include a transistor disposed in the backplane, an electrode disposed over the transistor, an OLED material disposed over the electrode. The electrode is connected to the transistor of the backplane. The OPD sub-pixel includes an electrode and an organic photodiode (OPD) material disposed over the electrode.

### CROSS-REFERENCE TO RELATED APPLICATIONS

This application claims benefit of U.S. Provisional Application No. 63/300,377, which is herein incorporated by reference in its entirety.

### BACKGROUND

### Field

Embodiments described herein generally relate to a display. More specifically, embodiments described herein relate to sub-pixel circuits, displays including sub-pixel circuits, and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits, displays including sub-pixel circuits, and methods of forming sub-pixel circuits that may be utilized in a display such as an OLED display.

### SUMMARY

In one embodiment, a display is provided. The display includes a backplane and a plurality of sub-pixel circuits separated by an overhang structures disposed over the backplane. The at least one sub-pixel circuit has sub-pixels defined by overhang structures. The sub-pixel circuit includes one or more organic light-emitting diode (OLED) sub-pixels and a photo-electrode sub-pixel. The OLED sub-pixels include a transistor disposed in the backplane, an electrode disposed over the transistor, an OLED material disposed over the electrode. The electrode is connected to the transistor of the backplane. The photo-electrode sub-pixel includes an electrode and a photo-electrode material disposed over the electrode.

In another embodiment, a sub-pixel circuit is provided. The sub-pixel circuit includes sub-pixel circuit includes one or more organic light-emitting diode (OLED) sub-pixels and a photo-electrode sub-pixel. The OLED sub-pixels include a transistor disposed in a backplane, an electrode disposed over the transistor, and an OLED material disposed over the electrode. The electrode is connected to the transistor of the backplane. The photo-electrode sub-pixel includes an electrode, and a photo-electrode material over the electrode.

In another embodiment, a method is provided. The method includes forming adjacent overhang structures on a backplane, wherein the overhang structures define an OLED sub-pixel area and a photo-electrode sub-pixel area. An organic light emitting diode (OLED) material is deposited in the OLED sub-pixel area and the photo-electrode sub-pixel area. A cathode is deposed over the OLED material. An encapsulation layer is deposited over the cathode. A first resist layer is formed in the OLED sub-pixel area. One or more exposed portions of the encapsulation layer are removed. One or more exposed portions of the OLED material are removed. The resist layer is removed. A photo-electrode material layer is deposited in the OLED sub-pixel area and the photo-electrode sub-pixel area. The encapsulation layer is deposited. A second resist layer is deposited in the photo-electrode sub-pixel area. One or more exposed portions of the photo-electrode material layer and encapsulation layer to form a photo-electrode material in the photo-electrode sub-pixel area are removed.

In another embodiment, a display includes a backplane and adjacent overhang structures disposed on the backplane. At least one overhang structure is disposed over a pixel defining layer (PDL) structure disposed over the backplane, a first structure disposed over the PDL structure, and a second structure disposed over the first structure. The overhang structure is defined by an extension of a second structure extending laterally past a first structure. At least one overhang structure defines an organic light-emitting diode (OLED) sub-pixel and a photo-electrode sub-pixel. The OLED sub-pixel includes a transistor disposed in a backplane, an electrode disposed over the transistor, and an OLED material disposed over the electrode. The electrode is connected to the transistor of the backplane. The photo-electrode sub-pixel includes an electrode and a photo-electrode material over the electrode.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted that the appended drawings illustrate only exemplary embodiments and are therefore not to be considered limiting of scope, as the disclosure may admit to other equally effective embodiments.

FIG. 1A is a schematic, top sectional view of a display having a first photo-electrode sub-pixel configuration according to embodiments.

FIG. 1B is a schematic, top sectional view of a display having a second photo-electrode sub-pixel configuration according to embodiments.

FIG. 1C is a schematic, top sectional view of a display having a third photo-electrode sub-pixel configuration according to embodiments.

FIG. 1D is a schematic, top sectional view of a display having a fourth photo-electrode sub-pixel configuration according to embodiments.

FIG. 1E a schematic, top sectional view of a display having a fifth photo-electrode sub-pixel configuration according to embodiments.

FIG. 1F a schematic, top sectional view of a display having a sixth photo-electrode sub-pixel configuration according to embodiments.

FIG. 1G a schematic, top sectional view of a display having a seventh photo-electrode sub-pixel configuration according to embodiments.

FIG. 1H a schematic, top sectional view of a display having an eighth photo-electrode sub-pixel configuration according to embodiments.

FIG. 2 is a schematic, cross-sectional view of a sub-pixel circuit according to embodiments.

FIG. 3 is a flow diagram of a method for forming display according to embodiments.

FIGS. 4A-4J are schematic, cross-sectional views of a backplane during the method for forming the display according to embodiments.

FIG. 5A is a schematic, cross-sectional view of a sub-pixel circuit according to embodiments.

FIG. 5B is a schematic, cross-sectional view of a sub-pixel circuit according to embodiments.

FIG. 5C is a schematic, cross-sectional view of a sub-pixel circuit having a line-type architecture according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits, displays including sub-pixel circuits, and a method of forming sub-pixel circuits that may be utilized in a display such as an organic light-emitting diode (OLED) display. Some configurations of the displays described herein include sub-pixel circuits. The sub-pixel circuits include one or more OLED sub-pixels and at least one sensor in a photo-electrode sub-pixel. The OLED sub-pixels and the photo-electrode sub-pixels are defined by adjacent overhang structures. The sensor is disposed in the photo-electrode sub-pixel and includes a photo-electrode material. The configurations described herein utilize sensors that are integrated to increase the transmittance of the display while eliminating the need for bezels and reducing dead zones in the display.

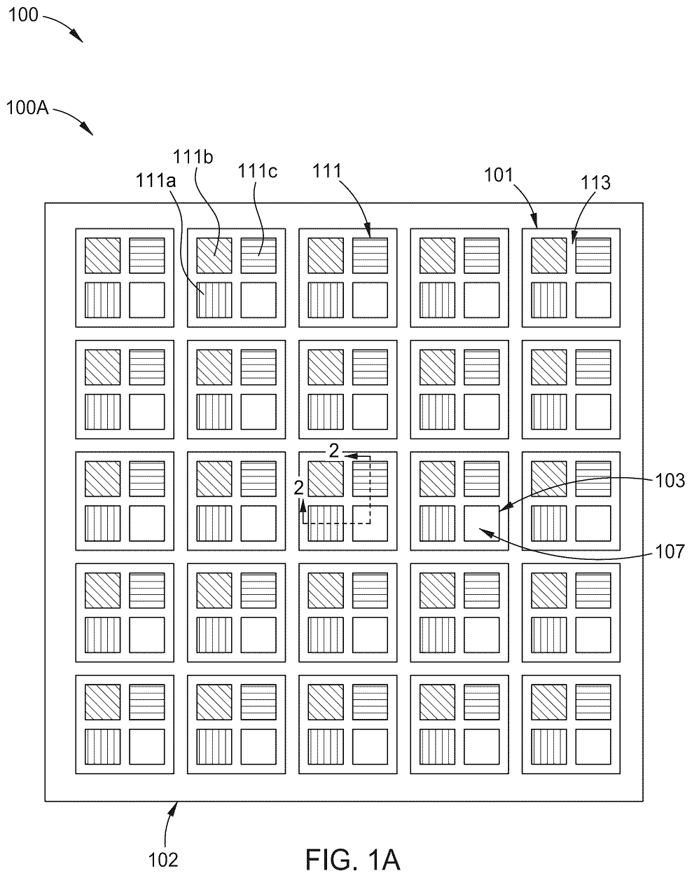

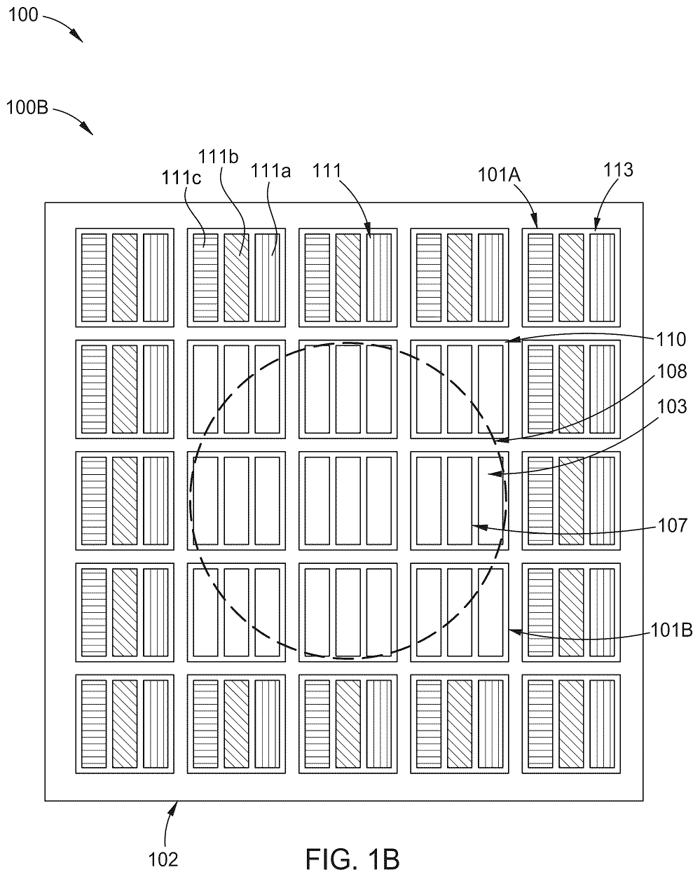

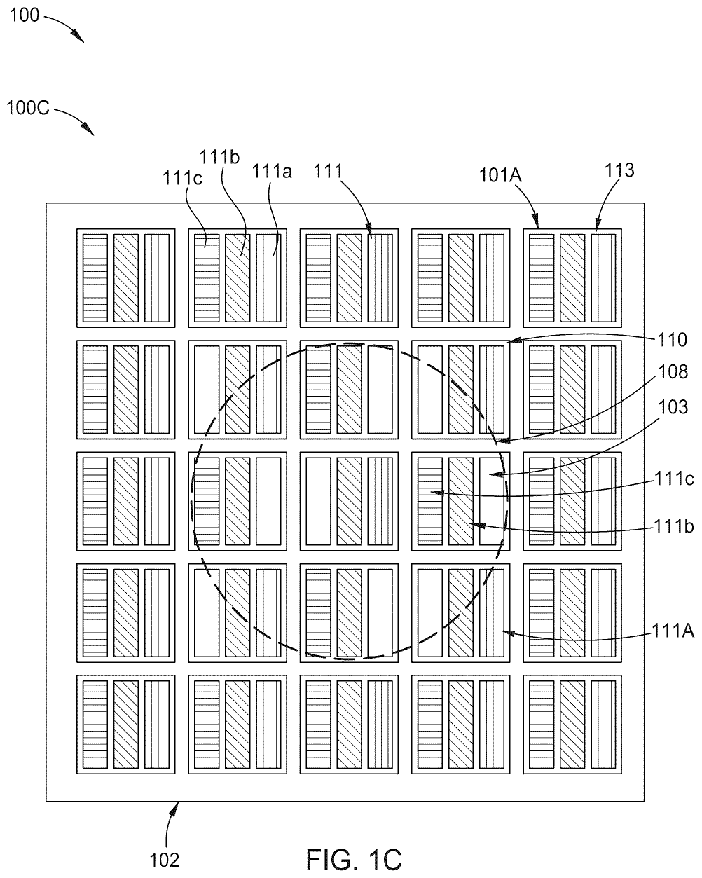

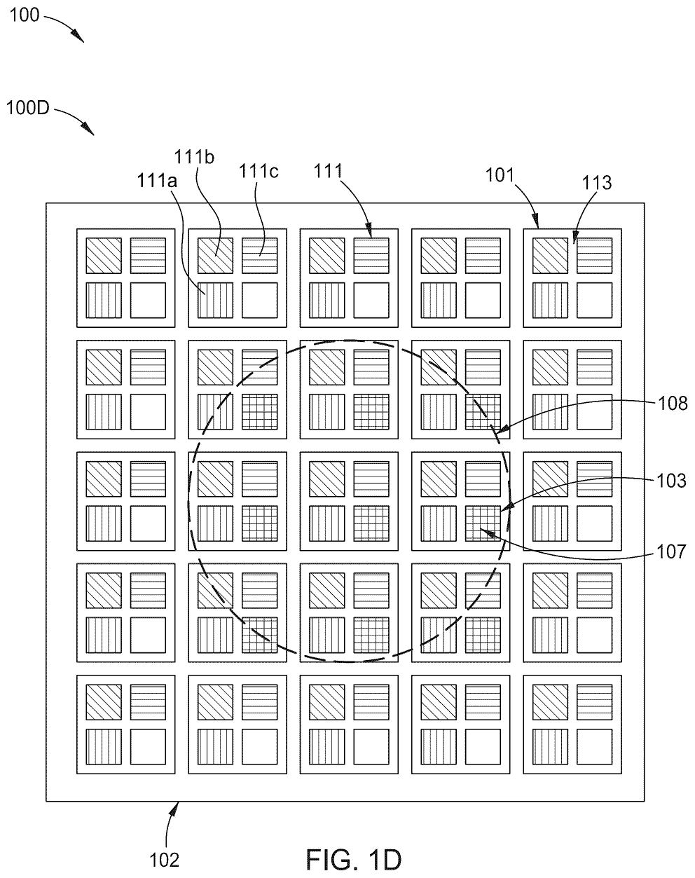

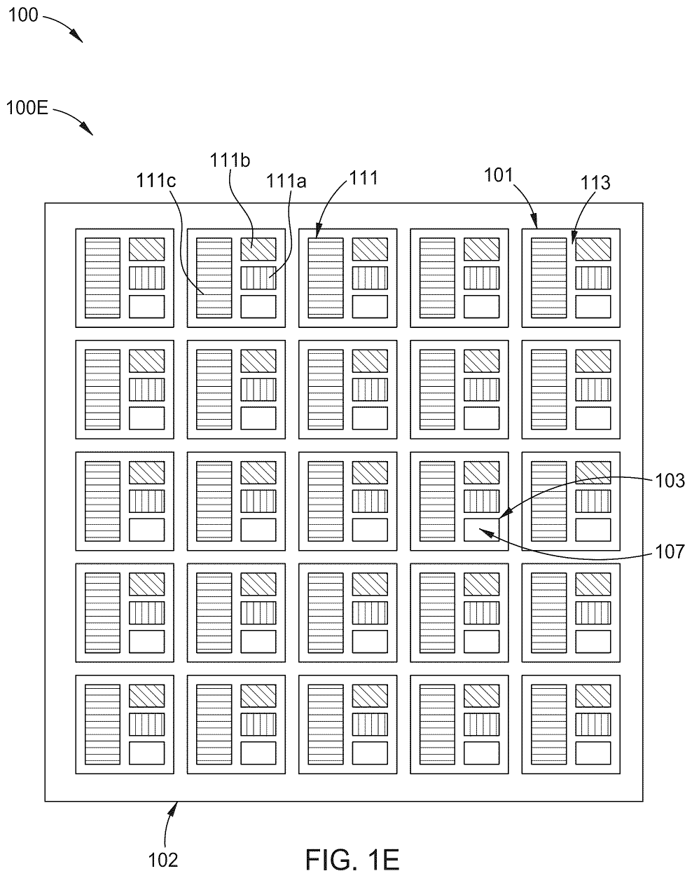

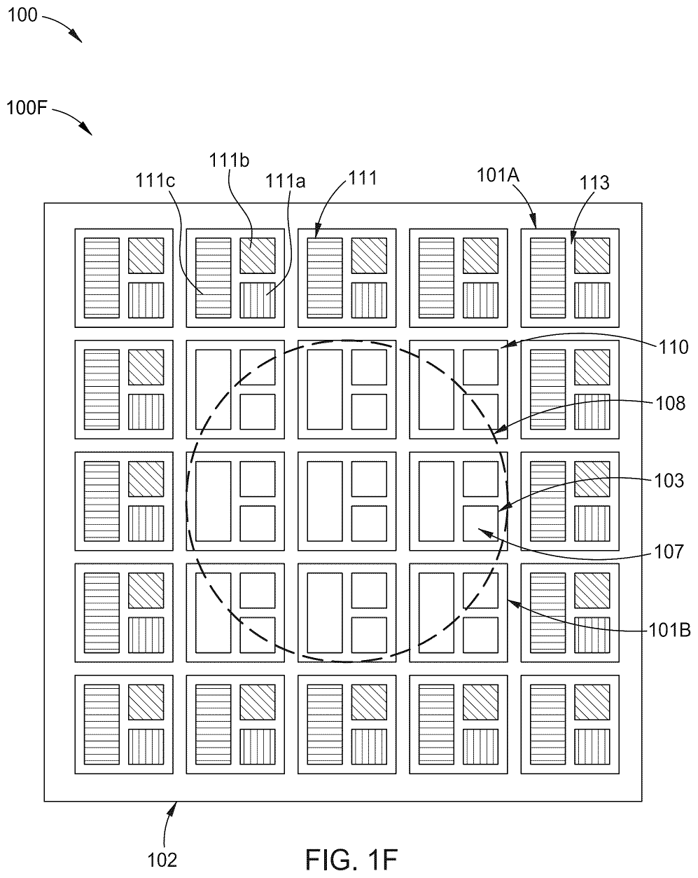

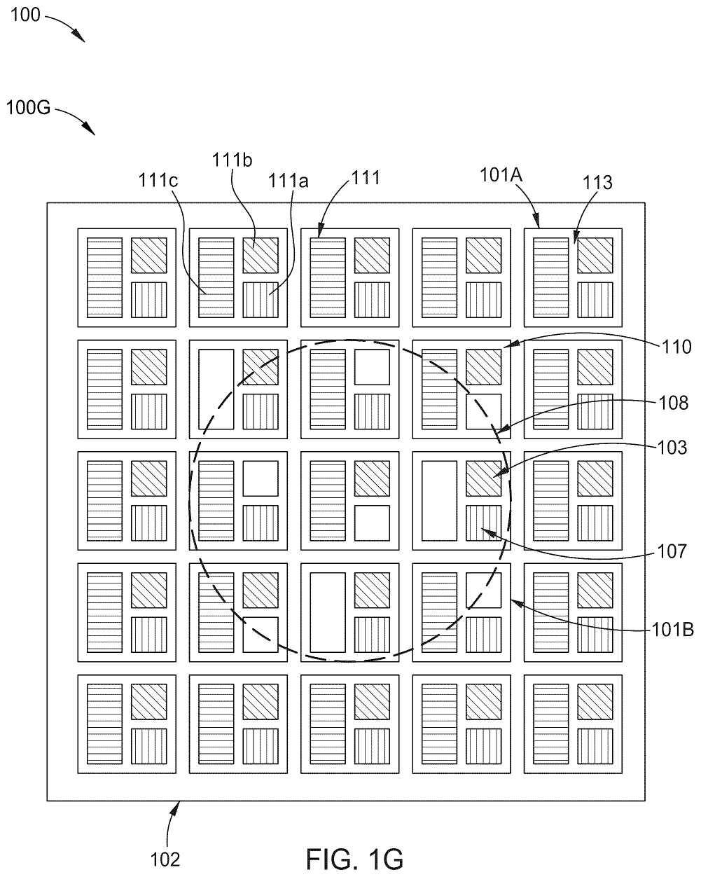

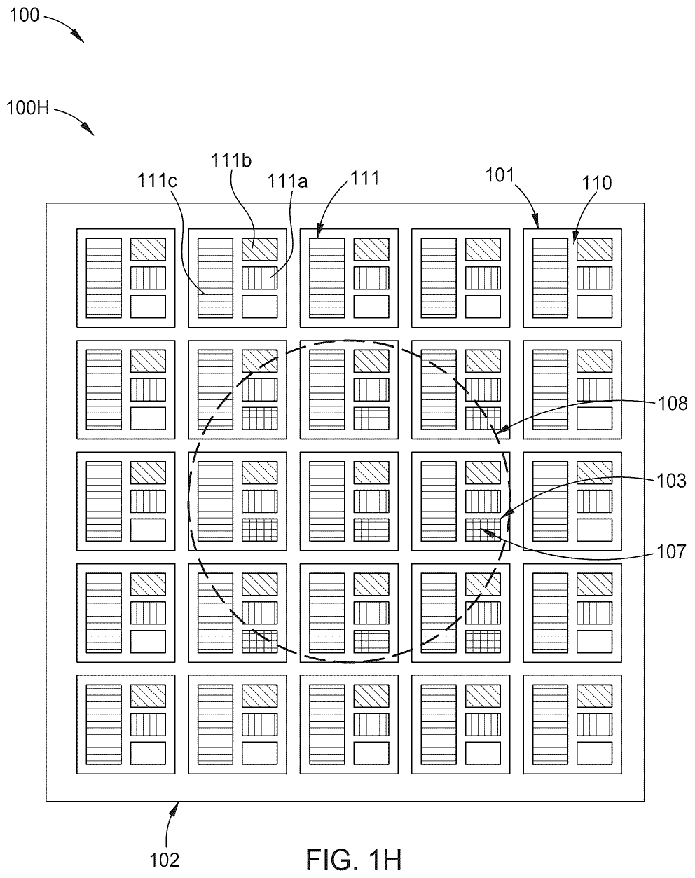

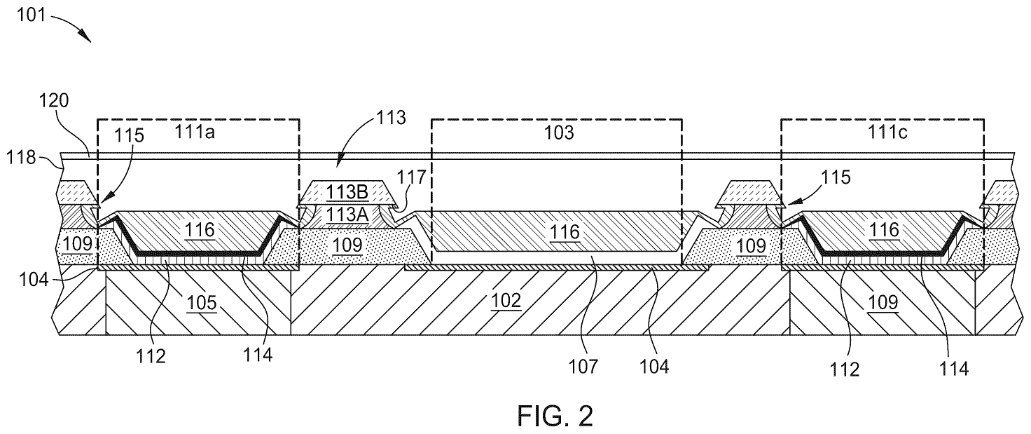

FIG. 1A is a schematic, top sectional view of a display 100 having a first photo-electrode sub-pixel configuration 100A. FIG. 2 is a schematic, cross-sectional view of a sub-pixel circuit 101. The display 100 of the first photo-electrode sub-pixel configuration 100A includes a plurality sub-pixel circuits 101. The sub-pixel circuit 101 includes a plurality of organic light emitting diode (OLED) sub-pixels 111 and a photo-electrode sub-pixel 103. The display 100 includes a backplane 102 (e.g., a substrate). The backplane 102 includes a plurality of transistors 105. The sensor 107 is disposed over the backplane 102 in the photo-electrode sub-pixel 103, as shown in FIG. 2. The photo-electrode sub-pixel 103 of the sub-pixels circuit 101 is configured such that light is received by the sensor 107. In some embodiments, the photo-electrode sub-pixel 103 of the sub-pixel circuit 101 is configured to emit light if the sensor 107 is coupled to or includes an emitter. The emitter may be an IR emitter or a light-emitting diode (LED). The sensor 107 is a photo-electrode material, such as an organic polymer or an organic small molecule. The photo-electrode material is configured to sense (i.e., absorb) light in order to generate a current.

Electrodes 104 may be patterned on the backplane 102 and are defined by adjacent pixel-defining layer (PDL) structures 109 disposed on the backplane 102. Some embodiments of the displays 100 of this disclosure have other structures defining the electrodes 104 and PDL structures 109 are not utilized. In some embodiments, which can be combined with other disclosures described herein, the PDL structures 109 are disposed on the backplane 102. The electrodes 104 are disposed on the backplane 102 between the PDL structures 109. In some examples, the PDL structures are partially disposed on the electrode 104, as shown in FIG. 2.

In one embodiment, the electrodes 104 may include metal-containing layers that are pre-patterned on the backplane 102. E.g., the electrodes 104 is a pre-patterned indium tin oxide (ITO) glass substrate. The metal-containing layers are configured to operate electrodes 104 of respective sub-pixels. The electrodes 104 include, but are not limited to, chromium, titanium, gold, silver, copper, aluminum, ITO, combinations thereof, or other suitably conductive materials. The electrodes 104 are connected to the transistors 105 of the backplane 102. In some embodiments, which may be combined with other embodiments described herein, the electrodes 104 of the OLED sub-pixels 111 are disposed above, e.g., disposed on, the transistors 105. In some embodiments, the electrode 104 is an anode for the OLED sub-pixels 111 and the photo-electrode sub-pixel 103. In other embodiments, the electrode 104 is an anode for the OLED sub-pixels 111 and a cathode for the photo-electrode sub-pixel 103.

The OLED sub-pixels 111 include at least a first OLED sub-pixel 111a, a second OLED sub-pixel 111b, and a third OLED sub-pixel 111c. While the Figures depict the first OLED sub-pixel 111a, the second OLED sub-pixel 111b, and the third OLED sub-pixel 111c, the sub-pixel circuits 101 of the embodiments described herein may include three or more OLED sub-pixels 111, such as a fourth and a fifth sub-pixel. Each OLED sub-pixel 111 has OLED material 112 configured to emit a white, red, green, blue or other color light when energized. The OLED material 112 is configured to convert an applied current into light. E.g., the OLED material 112 of the first OLED sub-pixel 111a emits a green light when energized, the OLED material of the second OLED sub-pixel 111b emits a blue light when energized, the OLED material of a third OLED sub-pixel 111c emits a red light when energized, and the OLED material of a fourth sub-pixel and a fifth sub-pixel emits another color light when energized.

Each OLED sub-pixel 111 and photo-electrode sub-pixel 103 is defined and separated by adjacent overhang structures 113. In embodiments including PDL structures 109, overhang structures 113 are disposed on an upper surface of each of the PDL structures 109. The overhang structures 113 include at least a second structure 113B disposed over a first structure 113A. Each overhang structure 113 includes an overhang 115. The overhang 115 is defined by an extension 117 of the second structure 113B extending laterally past an upper surface of the first structure 113A. The second structure 113B includes one of a non-conductive material, inorganic material, or metal-containing material. The first structure 113A includes one of a non-conductive material, inorganic material, or metal-containing material. The non-conductive material includes, but it not limited to, an inorganic silicon-containing material. E.g., the silicon-containing material includes oxides or nitrides of silicon, or combinations thereof. The metal-containing materials include at least one of a metal or metal alloy such as titanium (Ti), aluminum (AI), aluminum neodymium (AlNd), molybdenum (Mo), molybdenum tungsten (MoW), copper (Cu), or combinations thereof.

The inorganic materials of the first structure 113A and the second structure 113B include silicon nitride (Si₃N₄), silicon oxide (SiO₂), silicon oxynitride (Si₂N₂O), or combinations thereof. The overhang structures 113 are able to remain in place, i.e., are permanent. In one embodiment, which may be combined with other embodiments described herein, the first structure 113A includes an inorganic material, such as silicon, e.g. amorphous silicon, and the second structure 113B includes germanium, copper, chromium, gallium arsenide (GaAs), a group III element, a group IV element, a III-V compound semiconductor, or a combination thereof. In another embodiment, which may be combined with other embodiments described herein, the first structure 113A includes germanium, copper, chromium, gallium arsenide (GaAs), a group III element, a group IV element, a III-V compound semiconductor, or a combination thereof, and the second structure 113B includes an inorganic material, such as silicon, e.g. amorphous silicon. Thus, organic material from lifted off overhang structures that disrupt OLED performance would not be left behind. Eliminating the need for a lift-off procedure also increases throughput.

FIG. 1B is a schematic, top sectional view of a display 100 having a second photo-electrode sub-pixel configuration 100B. The display 100 of the second photo-electrode sub-pixel configuration 100B includes a plurality of OLED sub-pixel circuits 101A and a plurality of photo-electrode sub-pixel circuits 101B. A localized portion 108 of the display 100 has at least one photo-electrode sub-pixel circuit 101B. The sub-pixel circuits 101 outside the localized portion of the display 100 have at least one OLED sub-pixel circuit 101A which does not contain the photo-electrode material.

The photo-electrode sub-pixel circuits 101B include a plurality of photo-electrode sub-pixels 103 and the OLED sub-pixel circuits 101A include a plurality of OLED sub-pixels 111. Each OLED sub-pixel 111 is defined by the overhang structures 113. Each OLED sub-pixel 111 has OLED material 112 configured to emit a white, red, green, blue or other color light when energized. Each photo-electrode sub-pixel 103 is defined by the overhang structures 113.

FIG. 1C is a schematic, top sectional view of a display 100 having a third photo-electrode sub-pixel configuration 100C. The display 100 of the third photo-electrode sub-pixel configuration 100C includes a plurality sub-pixel circuits 101 and a plurality of OLED sub-pixel circuits 101A. The sub-pixel circuits 101 include a plurality of OLED sub-pixels 111 and a photo-electrode sub-pixel 103. The OLED sub-pixel circuits include a plurality of OLED sub-pixels 111. The plurality of sub-pixel circuits 101 are located within a localized portion 108 of the display 100 and have at least one photo-electrode sub-pixel 103 having a sensor 107. In some embodiments, the plurality of OLED sub-pixels 111 each have a green sub-pixel configured to emit green light when energized. The plurality of OLED sub-pixels 111 may alternate between blue sub-pixels configured to emit blue light when energized and red sub-pixels configured to emit red light when energized. Adjacent OLED sub-pixels 111 do not each include a blue sub-pixel without a red sub-pixel, or each include a red sub-pixel without a blue sub-pixel. The current density of the sub-pixels within the localized portion 108 may be greater than the current density outside of the localized portion 108.

FIG. 1D is a schematic, top sectional view of a display 100 having a fourth photo-electrode sub-pixel configuration 100D. The display 100 of the fourth photo-electrode sub-pixel configuration 100D includes a plurality sub-pixel circuits 101. The sub-pixel circuit 101 includes a plurality of organic light emitting diode (OLED) sub-pixels 111 and a photo-electrode sub-pixel 103. The plurality of sub-pixel circuits 101 located in a localized portion 108 of the display 100 have at least one photo-electrode sub-pixel 103 having a sensor 107.

FIG. 1E a schematic, top sectional view of a display having a fifth photo-electrode sub-pixel configuration according to embodiments. The display 100 of the fifth photo-electrode sub-pixel configuration 100E includes a plurality sub-pixel circuits 101. The sub-pixel circuits 101 include a plurality of organic light emitting diode (OLED) sub-pixels 111 a photo-electrode sub-pixel 103. The OLED sub-pixel circuit 101A includes a third OLED sub-pixel 111c that is larger than the first OLED sub-pixel 111a and the second OLED sub-pixel 111b.

FIG. 1F a schematic, top sectional view of a display having a sixth photo-electrode sub-pixel configuration according to embodiments. The display 100 of the sixth photo-electrode sub-pixel configuration 100F includes a plurality of OLED sub-pixel circuits 101A and a plurality of photo-electrode sub-pixel circuits 101B. A localized portion 108 of the display 100 has at least one photo-electrode sub-pixel circuit 101B. The sub-pixel circuits 101 outside the localized portion of the display 100 have at least one OLED sub-pixel circuit 101A which do not contain the photo-electrode material. The plurality of OLED sub-pixel circuits 101A includes a third OLED sub-pixel 111c that is larger than the first OLED sub-pixel 111a and the second OLED sub-pixel 111b. The at least one photo-electrode sub-pixel circuit 101B includes at least one photo-electrode sub-pixel 103 that is larger than the other photo-electrode sub-pixels 103.

FIG. 1G a schematic, top sectional view of a display having a seventh photo-electrode sub-pixel configuration according to embodiments. The display 100 of the seventh photo-electrode sub-pixel configuration 100G includes a plurality OLED sub-pixel circuits 101A and a plurality of sub-pixel circuits 101. The sub-pixel circuits 101 include a plurality of organic light emitting diode (OLED) sub-pixels 111 and a photo-electrode sub-pixel 103. The sub-pixel circuits 101 located in a localized portion 108 of the display 100 have at least one photo-electrode sub-pixel 103 having a sensor 107. In some embodiments, the plurality of OLED sub-pixels 111 each have a green sub-pixel configured to emit green light when energized. The current density of the sub-pixels within the localized portion 108 may be greater than the current density outside of the localized portion 108. The sub-pixel circuit 101 includes an OLED sub-pixel 111 that, in some embodiments, is larger than the other OLED sub-pixels 111 and the photo-electrode sub-pixel 103. In other embodiments, the sub-pixel circuit 101 includes a photo-electrode sub-pixel 103 that is larger than the OLED sub-pixels 111.

FIG. 1H a schematic, top sectional view of a display having an eighth photo-electrode sub-pixel configuration according to embodiments. The display 100 of the eighth photo-electrode sub-pixel configuration 100H includes a plurality sub-pixel circuits 101. The sub-pixel circuit 101 includes a plurality of organic light emitting diode (OLED) sub-pixels 111 and a photo-electrode sub-pixel 103. The sub-pixel circuits located in a localized portion 108 of the display 100 has at least one photo-electrode sub-pixel 103 having a sensor 107. The sub-pixel circuit 101 includes a third OLED sub-pixel 111c that is larger than the first OLED sub-pixel 111a, the second OLED sub-pixel 111b, and the photo-electrode sub-pixel 103 in the localized portion 108.

As shown in FIG. 2, each OLED sub-pixel 111 includes a cathode 114 disposed over the OLED material 112. The cathode 114 is includes a conductive material such as a metal. The cathode 114 may be formed from silver, magnesium, chromium, titanium, aluminum, indium tin oxide (ITO), APT, a compound or another suitably conductive material. The cathode 114 is disposed over the OLED material 112 and extends under the overhang structure 113. The cathode 114 may extend past an endpoint of the OLED material 112 without contacting the first structure 113A. The cathode 114 may contact the sidewall of the first structure 113A. In some embodiments, the cathode 114 may contact an auxiliary electrode or an assistant cathode. In other embodiments, the cathode 114 contacts the bus bars (not shown) outside of an active area of the sub-pixel circuits 101. An encapsulation layer 116 is disposed over the OLED material 112, the cathode 114, and at least a portion of the overhang structures 113 of each OLED sub-pixel 111. The encapsulation layer 116 may extend under at least a portion of the overhang structures 113 and along a sidewall of each of the first structure 113A and the second structure 113B.

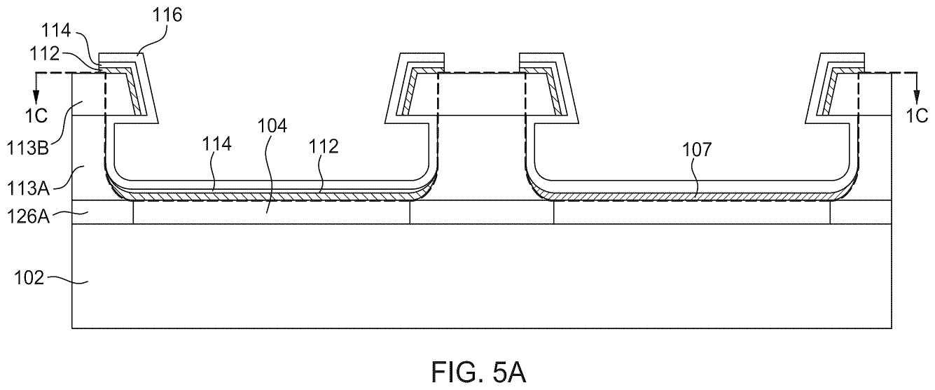

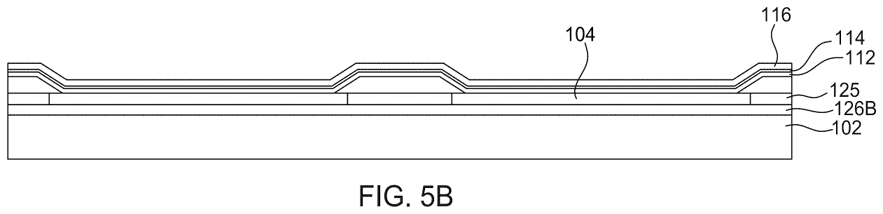

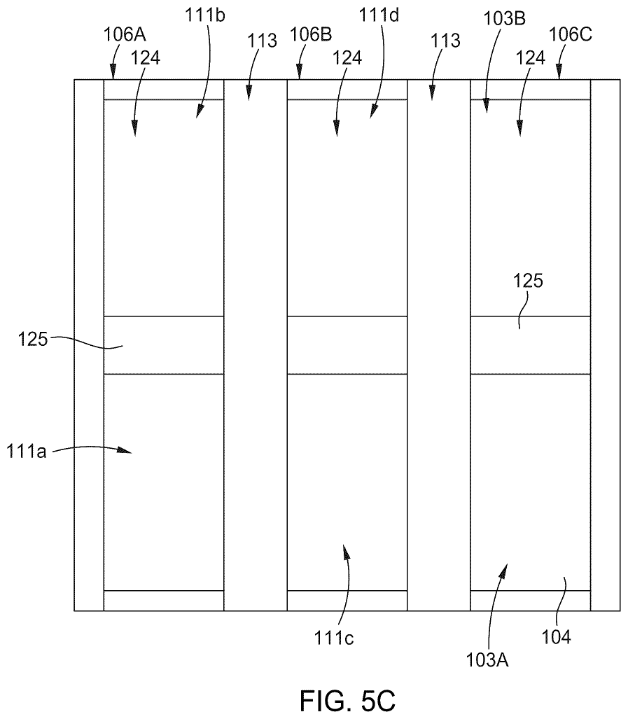

In some embodiments, as shown in FIGS. 5A-5C, the PDL structures 109 include a first pixel isolation structure (PIS) 126A and a second PIS 126B disposed over the backplane 102. The first PIS 126A is disposed along a line plane. The line plane extends along a first direction. The second PIS 126B is disposed along a pixel plane. The pixel plane extends along a second direction. The first direction is perpendicular to the second direction. Adjacent first PIS 126A and second PIS 126B define a respective sub-pixel and expose the electrode 104 of the respective sub-pixel circuit 101.

The sub-pixel circuit may have a plurality of sub-pixel lines (e.g., a first sub-pixel line 106A, a second sub-pixel line 106B, and a third sub-pixel line 106C). In embodiments, the first sub-pixel line 106A and the second sub-pixel line 106B may be OLED sub-pixel lines, while the third sub-pixel line 106C may be a photo-electrode sub-pixel line. The sub-pixel lines are adjacent to each other along the pixel plane. Each sub-pixel line includes at least two sub-pixels. E.g., the first sub-pixel line 106A includes a first OLED sub-pixel 111a and a second sub-pixel 111b, the second sub-pixel line 106B includes a third sub-pixel 111c and a fourth sub-pixel 111d, and the third sub-pixel line 106C includes a first photo-electrode sub-pixel 103A and second photo-electrode sub-pixel 103B. The first OLED sub-pixel 111a and the second OLED sub-pixel 111B are aligned along the line plane. The third OLED sub-pixel 111C and the fourth OLED sub-pixel 111D are aligned along the line plane. The first photo-electrode sub-pixel 111a and the second PD sub-pixel 111B are aligned along the line plane.

In some embodiments, the adjacent overhang structures 113 may include adjacent separation structures 125, with adjacent sub-pixels sharing the adjacent separation structures 125 in the line plane. The separation structures 125 are permanent to the sub-pixel circuits. The separation structures 125 define each sub-pixel of a sub-pixel line of the sub-pixel circuit. The separation structures 125 are disposed over an upper surface of the second PIS 126B. The line-type architecture shown in FIG. 5C includes a plurality of pixel openings 124. Each of pixel opening 124 is defined by overhang structures 113 in the pixel plane and separation structure 125 in the line plane, which define each sub-pixel line and subpixel of the line-type architecture 101C.

The OLED material 112 is disposed over and in contact with the electrode 104 and the separation structure 125 in the line plane. The cathode 114 is disposed over the OLED material 112 in the line plane. The encapsulation layer 116 is disposed over the cathode 114 in the line plane. The OLED material 112, the cathode 114, and the encapsulation layer 116 maintain continuity along the length of the line plane in order to apply current across each sub-pixel 106.

A global passivation layer 120 is disposed over the sub-pixel circuits 101. An intermediate layer 118 is disposed between the encapsulation layer 116, and the global passivation layer 120. In some embodiments, which may be combined with other embodiments described herein, a secondary layer is disposed between the encapsulation layer 116 and the intermediate layer 118 in the OLED sub-pixels 111.

The global passivation layer 120 and the intermediate layer 118 are transparent or semi-transparent. Thus, light is the emitted (if the sensor 107 is an emitter), or received by the sensor 107.

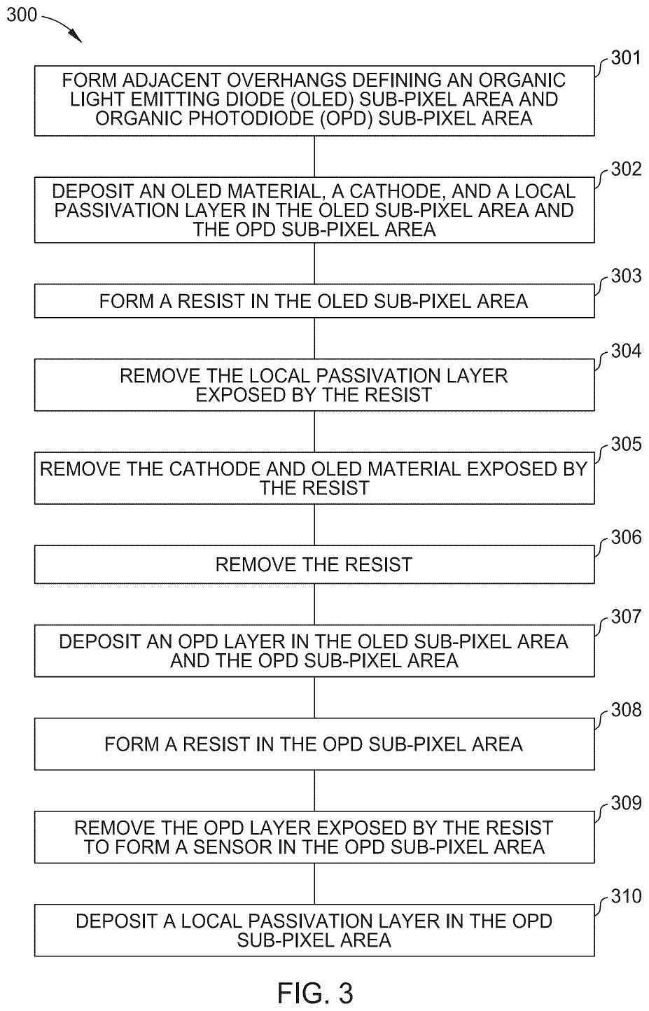

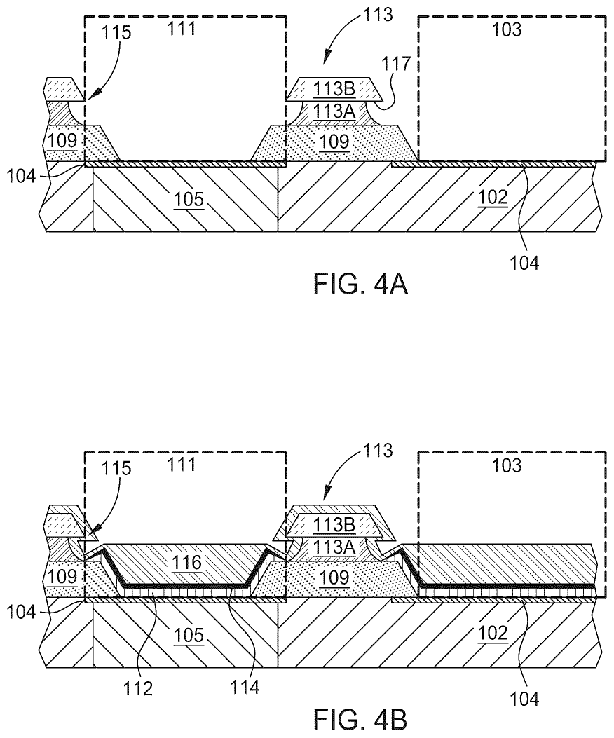

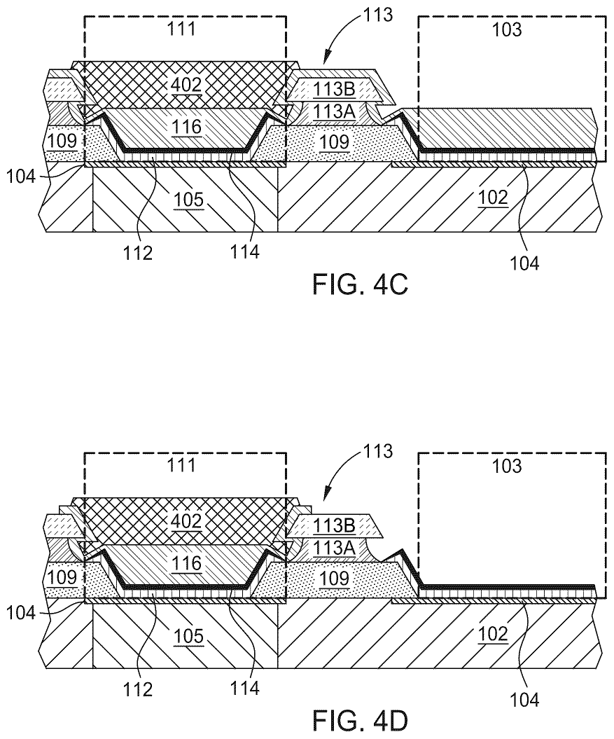

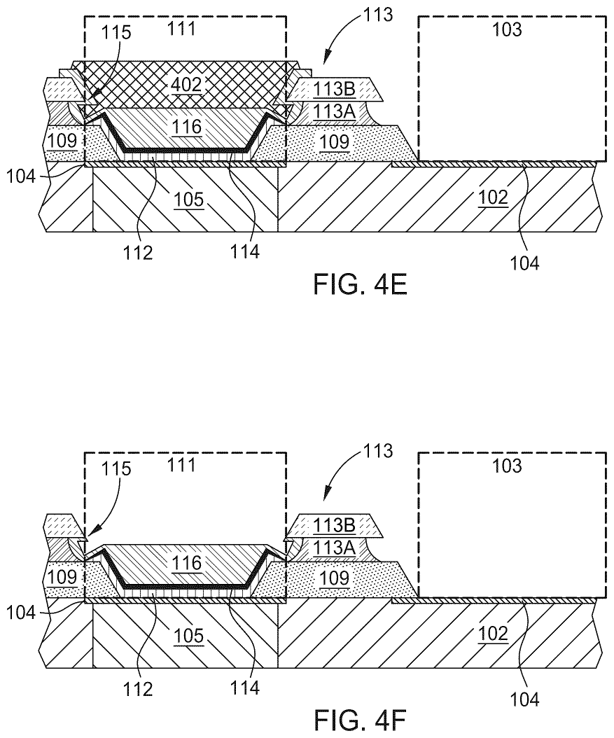

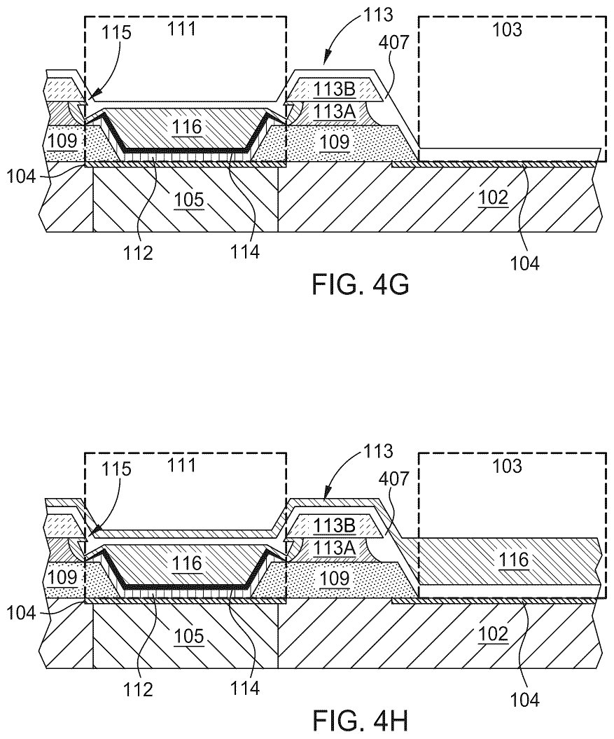

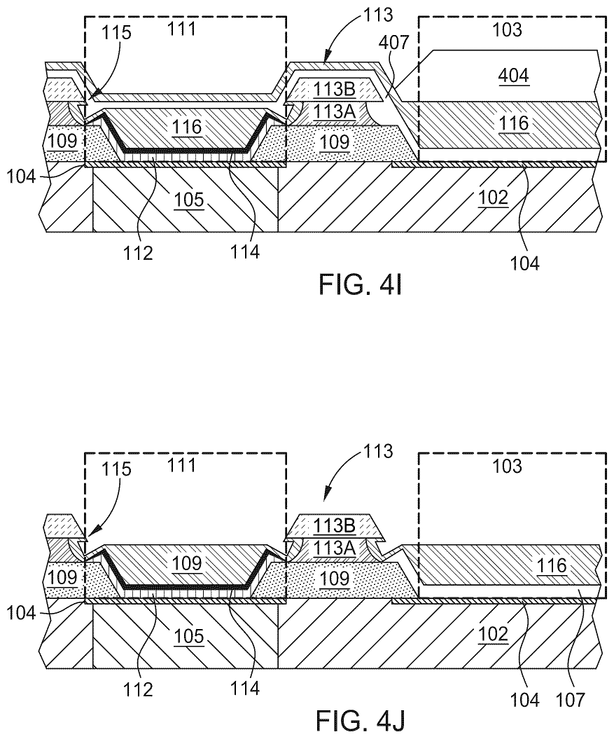

FIG. 3 is a flow diagram of a method 300 for forming display 100. FIGS. 4A-4J are schematic, cross-sectional views of a backplane 102 during the method 300 for forming the display 100. At operation 301, as shown in FIGS. 4A, the adjacent overhang structures 113 are formed. The overhang structures 113 of the embodiments of the display 100 includes overhang structures 113. The overhang structures 113 include at least a second structure 113B disposed over a first structure 113A. Each overhang structures 113 includes an overhang 115. The overhang 115 is defined by an extension 117 of the second structure 113B extending laterally past a sidewall of the first structure 113A. The overhang structures 113 are disposed over pixel-defining layer (PDL) structures 109. The PDL structures 109 are disposed over a backplane 102. An electrode 104 is disposed on the backplane 102 between the PDL structures 109. The backplane 102 includes a plurality of transistors 105. The overhang structures define an OLED sub-pixels 111 and a photo-electrode sub-pixel 103. In some embodiments, the OLED sub-pixels 111 and the photo-electrode sub-pixels include the electrode 104. In other embodiments, the OLED sub-pixels 111 include the electrode 104.

At operation 302, as shown in FIGS. 4B, an organic light emitting diode (OLED) material 112, a cathode 114, and an encapsulation layer 116 are deposited. The OLED material 112, the cathode 114, and the encapsulation layer 116 are deposited in the OLED sub-pixel 111 and the photo-electrode sub-pixel 103.

At operation 303, as shown in FIGS. 4C, a resist 402 is formed in the OLED sub-pixel 111. The resist 402 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist 402 determines whether the resist is a positive resist or a negative resist. The resist 402 disposed thereon is patterned to form a pixel opening of the OLED sub-pixel 111. The patterning is one of a photolithography, digital lithography process, or laser ablation process.

At operation 304, as shown in FIGS. 4D, the encapsulation layer 116 exposed by the resist 402 is removed from the photo-electrode sub-pixel 103.

At operation 305, as shown in FIGS. 4E, the cathode 114 and the OLED material 112 exposed by the resist 402 are removed from the photo-electrode sub-pixel 103. The cathode 114 is disposed over the OLED material 112 and extends under the overhang structure 113. The cathode 114 may extend past an endpoint of the OLED material 112 without contacting the first structure 113A. The cathode 114 may contact the sidewall of the first structure 113A. In some embodiments, the cathode 114 may contact an auxiliary electrode or an assistant cathode. In other embodiments, the cathode 114 contacts the bus bars (not shown) outside of an active area of the sub-pixel circuits 101.

At operation 306, as shown in FIGS. 4F, the resist 402 is removed from the OLED sub-pixel 111. At operation 307, as shown in FIGS. 4G, a photo-electrode material layer 407 is deposited. The photo-electrode material layer 407 is deposited in the OLED sub-pixel 111 and the photo-electrode sub-pixel 103.

At operation 308, as shown in FIGS. 4H, the encapsulation layer 116 is deposited in the photo-electrode sub-pixel 103. The encapsulation layer 116 is deposited using an evaporation deposition process.

At operation 309, as shown in FIGS. 41, a resist 404 is formed in the photo-electrode sub-pixel 103. The resist 404 is a positive resist or a negative resist. The chemical composition of the resist 404 determine whether the resist 404 is a positive resist or a negative resist. The resist 404 is patterned to protect the photo-electrode sub-pixel 103 from the subsequent etching processes. The patterning is one of a photolithography, digital lithography process, or laser ablation process.

At operation 310, as shown in FIGS. 4J, the photo-electrode material layer 407 and encapsulation layer 116 exposed by the resist 404 are removed from the OLED sub-pixel 111 to form a sensor 107. The sensor may be disposed over the electrode 104.

In summation, displays described herein include the sub-pixel circuits. The sub-pixel circuits include one or more OLED sub-pixels and at least one sensor in a photo-electrode sub-pixel. The OLED sub-pixels and the photo-electrode sub-pixels are adjacent to the overhang structures and an adjacent sub-pixel circuit. The sensor is disposed in the photo-electrode sub-pixel and includes a photo-electrode material. The configurations described herein utilize sensors that are integrated to increase the transmittance of the display while eliminating the need for bezels and reducing dead zones in the display.

While the foregoing is directed to embodiments of the present disclosure, other and further embodiments of the disclosure may be devised without departing from the basic scope thereof, and the scope thereof is determined by the claims that follow.

What is claimed is:

1. A display, comprising:
a backplane;
a plurality of sub-pixel circuits separated by adjacent overhang structures disposed over the backplane, at least one sub-pixel circuit has sub-pixels defined by adjacent overhang structures, wherein the sub-pixel circuit comprises:
one or more organic light-emitting diode (OLED) sub-pixels comprising:
a transistor disposed in the backplane;
an electrode disposed over the transistor, the electrode being connected to the transistor of the backplane; and
an OLED material disposed over the electrode; and
a photo-electrode sub-pixel comprising:
an electrode; and
a photo-electrode material disposed over the electrode.

2. The display of claim 1, wherein the electrode comprises chromium, titanium, gold, silver, copper, aluminum, ITO, combinations thereof.

3. The display of claim 1, wherein the electrode comprises metal-containing layers that are pre-patterned on the backplane.

4. The display of claim 1, where each over overhang structure is defined by an extension of a second structure extending laterally past a first structure.

5. The display of claim 1, wherein the photo-electrode material comprises an organic polymer or an organic small molecule.

6. The display of claim 1, wherein the photo-electrode material further comprises an emitter.

7. The display of claim 6, wherein the emitter is an IR emitter or a light-emitting diode (LED).

8. A sub-pixel circuit, comprising:
one or more organic light-emitting diode (OLED) sub-pixels comprising:
a transistor disposed in a backplane;
an electrode disposed over the transistor, the electrode being connected to the transistor of the backplane; and
an OLED material disposed over the electrode; and
a photo-electrode sub-pixel comprising:
an electrode; and
a photo-electrode material over the electrode.

9. The sub-pixel circuit of claim 8, wherein sub-pixel of the sub-pixel circuit is defined by adjacent overhang structures.

10. The sub-pixel circuit of claim 9, each over overhang structure is defined by an extension of a second structure extending laterally past a first structure.

11. The sub-pixel circuit of claim 8, wherein the electrode comprises chromium, titanium, gold, silver, copper, aluminum, ITO, combinations thereof.

12. The sub-pixel circuit of claim 8, wherein the photo-electrode material further comprises an emitter.

13. The sub-pixel circuit of claim 12, wherein the emitter is an IR emitter or a light-emitting diode (LED).

14. The sub-pixel circuit of claim 8, wherein the photo-electrode material comprises an organic polymer or an organic small molecule.

15. A method, comprising:
forming adjacent overhang structures on a backplane, wherein the overhang structures define an OLED sub-pixel area and an organic photodiode (OPD) sub-pixel area;
depositing an organic light emitting diode (OLED) material in the OLED sub-pixel area and the OPD sub-pixel area;
depositing a cathode over the OLED material;
depositing an encapsulation layer over the cathode;
forming a first resist layer in the OLED sub-pixel area;
removing one or more exposed portions of the encapsulation layer;
removing one or more exposed portions of the OLED material;
removing the resist layer;
depositing an OPD material layer in the OLED sub-pixel area and the OPD sub-pixel area;
depositing the encapsulation layer;
forming a second resist layer in the OPD sub-pixel area; and
removing one or more exposed portions of the OPD material layer and encapsulation layer to form a OPD material in the OPD sub-pixel area.

16. The method of claim 15, wherein the OPD material comprises an organic polymer or an organic small molecule.

17. The method of claim 15, wherein the overhang structures comprise at least a second structure disposed over a first structure.

18. The method of claim 15, wherein the organic photodiode comprises an organic polymer or an organic small molecule.

19. The method of claim 15, wherein an electrode is disposed on the backplane.

20. The method of claim 19, wherein the OPD material is disposed over the electrode.
